(19) United States
(12) Patent Application Publication
(10) Pub. No.: US 2014/0224315 A1
(43) Pub. Date: Aug. 14, 2014

(54) OPTICAL DEVICE USING 3-DIMENSIONAL NANOPARTICLE STRUCTURE

(71) Applicants: Global Frontier Center for Multiscale Energy Systems, Seoul (KR); SNU R&DB Foundation, Seoul (KR)

(72) Inventors: Kinam Jung, Seoul (KR); Jung Suk Hahn, Seoul (KR); Petro Pikhitsa, Seoul (KR); Hoseop Choi, Seoul (KR); Kyungyeon Ha, Seoul (KR); Seung Ryul Noh, Seoul (KR); Woong Sik Kim, Seoul (KR); Man Soo Choi, Seoul (KR)

(73) Assignees: SNU R&DB Foundation, Seoul (KR); Global Frontier Center for Multiscale Energy Systems, Seoul (KR)

(21) Appl. No.: 14/233,081

(22) PCT Filed: Jan. 30, 2013
(86) PCT No.: PCT/KR2013/000744

§ 371 Date: Jan. 15, 2014

(30) Foreign Application Priority Data
Jul. 13, 2012 (KR) 10-2011-0076887

(51) Int. Cl. B82B 1/00; H01L 31/0236

(52) U.S. Cl. CPC B82B 1/008; H01L 31/02366
USPC 136/256; 428/208; 427/569

(57) ABSTRACT

The present invention relates to a method for manufacturing a nanoparticle structure by focused patterning of nanoparticles, and a nanoparticle structure obtained by the above method. The method of the present invention is characterized by comprising the steps of: first of all, accumulating ions generated by corona discharge on a substrate where a micro/nano pattern is formed; inducing charged nanoparticles and ions generated by spark discharge to the micro/nano pattern of the substrate; and then focused depositing on the micro/nano pattern. According to the method of the present invention, an elaborate nanoparticle structure, which has 3-dimensional shape having complicated structure, can be effectively manufactured.

### FIELD OF THE INVENTION

The present invention relates to a 3-dimensional structure assembled with nanoparticles and a method for manufacturing thereof, and specifically, an optical device using a nanoparticle structure formed by focused patterning of charged nanoparticles generated by spark discharge, and having more elaborate 3-dimsional shape, and a method for manufacturing thereof.

### BACKGROUND OF THE INVENTION

Nanopatterning technique, which manufactures micro/nano-sized structure by depositing selectively controlled charged nanoparticles to a desired position, is expected to be useful for developing quantum devices and nanobio devices which will lead next generation industries.

As one example of the charged nanoparticle patterning technique, a method that a substrate is electrically charged by using electron beam or ion beam, and then charged nanoparticles having opposite polarity are deposited thereto is known. However, this method has a limit that it takes too much time because the method for charging a substrate with electricity is series type, and it can be only used in the case of non-conductive substrate because the substrate surface is charged with electricity by using electron beam or ion beam.

Further, a technique, which forms a photoresist on a substrate, patterns the photoresist by using photolithography and the like, and then introduces and deposits only charged nanoparticles to the pattern by using electrostatic force without an ion accumulating process, is reported. However, the above technique can conduct patterning of highly pure nanoparticles generated in the vapor state, but does not accumulate ions on the photoresist pattern. Accordingly, many nanoparticles can also be deposited at the undesired position, i.e., on the photoresist surface, as well as on an electrified substrate.

On the other hand, Raman spectroscopy is a technique which can make a great contribution to a bio field. However, there is still no commercialization or development of products using the Raman spectroscopy technique because it is not practical due to very weak signal obtained from the technique thereof. Accordingly, studies enhancing Raman signal are being actively carried out.

Among the methods enhancing signal size, methods, which uses surface plasmon phenomenon using resonance of free electrons on the metal surface, are being studied at many laboratories. Through the surface plasmon phenomenon, wherein free electrons of a metal are combined with light from outside and collectively vibrate, the electric field intensity dramatically and locally increases by the phenomenon, and Raman signal may be intensified by using this phenomenon properly.

Accordingly, the present applicants suggested a method for manufacturing a nanoparticle structure having 2-dimensional or 3-dimensional figure by focused patterning of nanoparticles in Korean Patent Publication No. 10-2009-0089787 (published on Aug. 24, 2009). The method can effectively manufacture a nanoparticle structure of 2-dimensional or 3-dimensional shape regardless of polarity of nanoparticle or ion, by generating bipolar charged nanoparticles and ions at the same time by means of spark discharge, introducing the particles thereof into a reactor where a patterned substrate exists, and then applying an electric field.

Thus, the present inventors studied a method, which can manufacture a nanoparticle assembly structure having elaborate 3-dimensional shape by upgrading said method.

### [Prior Art Document]

### [Patent Document]

(Patent Document 1) Korean Patent Publication No. 10-2009-0089787 (Published on Aug. 24, 2009)

### [Non-Patent Document]

(Non-Patent Document 1) Novel surface enhanced Raman spectroscopy substrate based on 3-dimensional nanoparticle structure, Han, jungseok, Graduate School of Seoul National University, 2012.2.

### SUMMARY OF THE INVENTION

Accordingly, the present invention provides a method for manufacturing a 3-dimensional nanoparticle structure, particularly a complicated and elaborate structure, by generating bipolar charged nanoparticles and ions simultaneously or separately and focusing them on a patterned substrate.

In order to accomplish one object of the present invention, the present invention provides a method for manufacturing a nanoparticle structure, which comprises the steps of:

1) locating a substrate, which has a micro/nano pattern formed by a mask layer having a perforated pattern, in a reactor, and then applying electric field;

2) generating ions by corona discharge, and then accumulating the ions on the micro/nano pattern of the substrate, which is located in the reactor;

3) forming charged nanoparticles and ions by spark discharging nanoparticle precursors in a spark discharge chamber; and

4) introducing the charged nanoparticles and ions into the reactor, and then focused-depositing the nanoparticles charged with the same polarity with the ions accumulated on the micro/nano pattern of the step 2), into the perforated part of the micro/nano pattern of the substrate.

According to one preferred embodiment of the present invention, the corona discharge of the step 2) may be generated by applying a voltage ranging from 1 kV to 10 kV to a corona discharge chamber.

Further, the spark discharge of the step 3) may be generated by applying a voltage ranging from 5 kV to 10 kV to a spark discharge chamber.

In the present invention, the nanoparticle precursors may be conductive materials, conductive materials coated with non-conductive materials or semiconductive materials.

According to one preferred embodiment of the present invention, the electric field of the step 1) may be formed by applying a voltage ranging from −5 kV to 5 kV in the reactor.

According to one preferred embodiment of the present invention, it is preferred that the ions generated in the step 2) and the charged nanoparticles and the ions generated in the step 3) are introduced into the reactor of the step 3) by using a carrier gas selected from nitrogen, helium and argon.

The 3-dimensional nanoparticle structure manufactured by the method of the present invention may show a petal shape, and particularly, it may be image of a flower having 5 or more, preferably 6 to 8 petals.

Further, the nanoparticle structure may consist of single nanoparticles or mixed nanoparticles of two or more types.

In this description, the term “micro/nano pattern” refers to a pattern having several nm to tens of μm width, and it may have various shapes; the term “nanoparticle structure” refers to a structure having broad range of diameter of several nm to several μm, which contains a molecular level cluster and is formed by accumulation of several nm to several μm nanoparticles; and the term “nanoparticle structure array” refers to an assembly of the nanoparticle structures.

### Advantageous Effects of the Invention

The 3-dimensional structure, manufactured by the method according to the present invention, can manufacture 3-dimensional nanoparticle structures with various structures of more complicated and elaborate shape having wide range of diameter from several nanometers to several micrometers, for example, an image of a flower having 5 or more petals, and this nanoparticle structure may be applied to optical and electric devices, for example, biosensors, solar cells and the like.

### BRIEF DESCRIPTION OF DRAWINGS

The above and other objects and features of the present invention will become apparent from the following description of the invention taken in conjunction with the following accompanying drawings, which respectively show:

FIG. 1 illustrates a principle of focused deposition of nanoparticles occurring in a reactor;

FIG. 2 is a schematic diagram of a device for manufacturing a 3-dimensional structure assembled with nanoparticles according to one embodiment of the present invention;

FIG. 3 shows various shapes of a micro/nano pattern;

FIG. 4 describes a process forming a flower shape by focusing nanoparticles according to the present invention;

FIG. 5 illustrates shapes of micro/nano patterns used in Examples;

FIG. 6 shows scanning electron microscope (SEM) images of nanoparticle structure arrays formed by using the pattern of FIG. 4;

FIG. 7 shows scanning electron microscope (SEM) images of nanoparticle structure arrays formed in other Examples; and

FIG. 8 shows the result of measuring surface-enhanced Raman scattering (SERS) against the nanoparticle structure array manufactured in Example 1.

### DETAILED DESCRIPTION OF THE INVENTION

The present invention relates to a method for manufacturing a 3-dimensional structure from nanoparticles by using electrostatic focused patterning method, and the key idea of the electrostatic focused patterning comes from the focusing effect of charged nanoparticles by using an electrostatic lens. When inserting ions and charged nanoparticles to the air, the ion having high electric mobility arrives on the substrate surface ahead. On the substrate surface, a mask layer having a perforated pattern is located, and the ions are accumulated only on the non-conductive mask layer, and all ions on the conductive substrate layer are removed. A convex equipotential line as an electrostatic lens is formed by the ions accumulated on the non-conductive mask layer, and the charged nanoparticles move to the direction perpendicular to the equipotential line and adhere to the desired position of the substrate.

This is the principle of the electrostatic focused patterning, and the particles continuously accumulated by the said way grow larger than the thickness of the mask layer, and a 3-dimensional structure having a flower shape is formed by the antenna effect and scaffold effect. At this time, when the amount of the ions accumulated on the surface of the non-conductive mask layer becomes larger, more effective electrostatic focused patterning is possible, and by properly controlling the perforated pattern of the mask layer, a structure assembled with nanoparticles with complicated and elaborate 3-dimensional shape can be obtained.

There are many curves on this 3-dimensional structure, and plasmon phenomenon can be induced by depositing gold or silver thereon. Then, the intensity of an electric field becomes stronger locally between leaves due to the interaction between the structures, and the place, where the electric field is shown strongly like this, is called a hotspot. The surface plasmon phenomenon actively occurs at this hotspot, and Raman signal may be strongly enhanced by this action. The more complicated the structure of the 3-dimensional structure becomes, and the lager the interaction between the structures becomes, the more the number of the hotspot becomes, and this may enhance the Raman signal.

Unlike the case of a spherical particle, the flower-shaped nanostructure may be applied to a catalyst or a substrate material of a surface-enhanced Raman spectroscopy (SERS) due to anisotropy of the shape and the like, and particularly, when the structure wherein nanoparticles are accumulated to a flower shape is used as a substrate of the surface-enhanced Raman spectroscopy, the signal is highly enhanced, and thereby show excellent measuring sensitivity.

Hereinafter, the present invention will be described in detail with reference to the accompanying drawings.

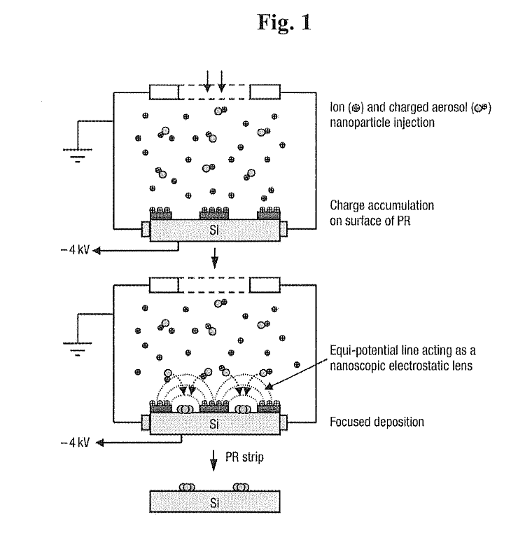

FIG. 1 describes a principle of nanoparticle patterning according to the present invention.

Before the particles are focused, ions are accumulated on the surface of a non-conductive mask layer having a perforated pattern or photoresist (PR) (for example, SiO₂) on top of a substrate (for example, silicon). A corona discharger generates positive ions of inert gas (for example, nitrogen), and those are mixed with nanoparticles positively charged (for example, copper particles) and then supplied into a reactor (electrostatic chamber). A proper electric field is applied between the patterned substrate and the entrance of the chamber.

In the present invention, the ion insertion is important. The electric field plane, which was flat in the early stage, is distorted as the ions are accumulated on the surface of the non-conductive mask layer (PR), and thereby forms a curved surface as shown in dotted line in FIG. 1. Like this, the curved potential surface plays a role of an electrostatic focusing lens formed around the PR pattern, and thereby makes the charged nanoparticles be focused at the center of the exposed surface.

Namely, when enough ions are accumulated on the PR, those ions form a convex equipotential line, and the line acts as a nano-sized electrostatic focusing lens when the charged nanoparticles approach. Further, the near field caused by the positive charge on the PR gets off the PR surface the particles, which are to attach thereto, because the field is toward outside of the surface, and prevents the deposition of the ions on the PR. Finally, when the PR is removed, the feature-sized nanoparticle array, which is much smaller than the initial PR pattern, can be obtained.

If the ions are not inserted, there is a problem that the nanoparticles are deposited on the entire part as well as on the PR surface and the exposed substrate surface because the potential plane remains flat until the nanoparticles are fully deposited.

Herein, the polarities of the ions and the nanoparticles on the PR should be same each other, and if the polarities are different each other, those meet each other and are neutralized, and then the electrostatic lens disappears.

In order to remove the ions deposited on the substrate, it is preferred to apply negative charge to the substrate. Because the PR is a non-conductive material, the ions on the PR do not disappear even if negative voltage is applied. The charged nanoparticles move to the direction perpendicular to the equipotential line, and therefore, those nanoparticles can be focused at the center of the exposed substrate surface of the PR pattern.

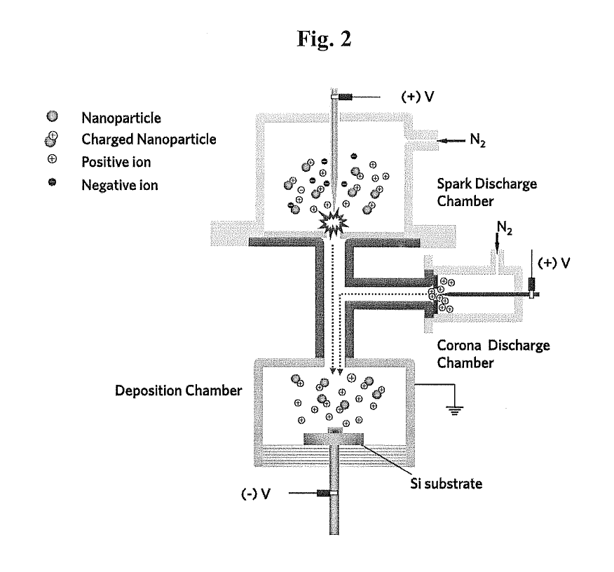

FIG. 2 illustrates a device used for conducting the method of the present invention. The method for manufacturing the nanoparticle structure according to the present invention now will be described in detail with reference to FIG. 2.

First of all, in the step 1) of the present invention, a substrate, which has a micro/nano pattern by a mask layer having a perforated pattern, is located on the electrode of a reactor (deposition chamber), whose body is earthed, and whose inside is equipped with the electrode; and then an electric field is formed inside the reactor by applying voltage, preferably from −5 kV to 5 kV, by using a voltage supply means, so as to make the polarity of the field opposite to that of the charged nanoparticles, which are desired to be deposited on the electrode. At this time, the mask layer having the micro/nano pattern may be formed by patterning a photoresist or a dielectric by a conventional photo process or an electron beam-lithography process, or by closely adhering the patterned-mask having a dielectric surface on the substrate. The photoresist and the substrate used in the present invention may be usual things, and the surface of the substrate may be a conductive material, a semi-conductive material or a non-conductive material.

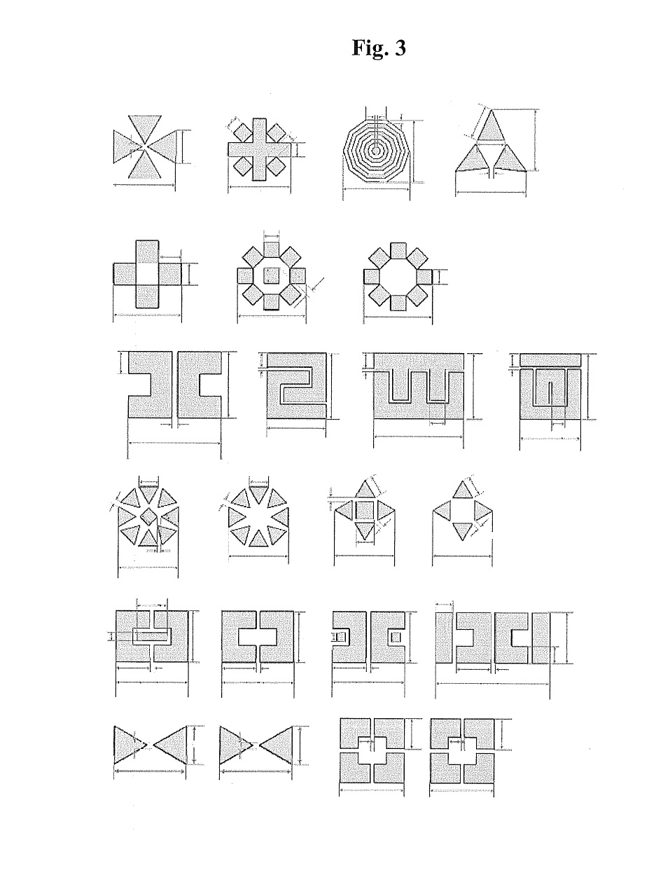

The shape of the micro/nano pattern is important to form the initial 2-dimensional structure and the 3-dimensional structure of various and delicate nanoparticle structures. Examples of the pattern used for forming the delicate nanoparticle assembly structures according to the present invention are as illustrated in FIG. 3, but not limited thereto (Gray part in FIG. 3 is the perforated part).

In the step 2) of the method according to the present invention, ions are generated by general corona discharge, and transferred to the reactor, and then accumulated on mask layer on the substrate. Specifically, the corona discharge generates a heterogeneous electric field between a tungsten needle and a plate. Air is an insulator, but it is electrically broken down at high enough voltage and becomes conductive. Depending on the shape of the electric field, this electrolysis causes arc or corona discharge, and electrons are accelerated to a certain speed at a corona region, thereby generating free ions and positive ions around a wire.

In the present invention, it is important to insert the ions more and earlier than particles on the non-conductive mask layer for forming the electrostatic lens, and for this, a corona discharger is used.

In the step 3) of the method according to the present invention, positive ions and positively-charged nanoparticles and negative ions and negatively-charged nanoparticles are generated simultaneously or separately by spark discharge.

The positive ions and positively-charged nanoparticles and the negative ions and negatively charged nanoparticles may be generated, for example, in a spark discharge chamber, which is equipped with a plate having the diameter of several centimeters and tip-shaped nanoparticle precursors having the diameter of several millimeters. Specifically, the positive ions and positively-charged nanoparticles and the negative ions and negatively charged nanoparticles can be generated simultaneously by spark discharge in the chamber, by earthing the plate, connecting a voltage supply means to the tip, and then applying voltage of, preferably 5 kV to 10 kV. Further, as occasion demands, monopolar ions can be generated separately by controlling voltage. For example, only the positive ions can be selectively generated in the chamber by applying voltage of 3 kV to 4 kV.

In the present invention, the material used as the precursor equipped in the spark discharge chamber may be a conductive material selected from gold, copper, tin, indium, ITO, graphite and silver; a conductive material coated with a non-conductive material selected from cadmium oxide, iron oxide and tin oxide; or a semi-conductive material selected from silicone, GaAs and.

The size of the nanoparticles generated by spark discharge may be controlled from 1 to 50 nm, and it may be 1 to 20 nm preferably, and 3 to 10 nm most preferably. According to one preferred embodiment of the present invention, in the case of copper, nanoparticles having particle diameter of 3 nm or less may be generated. The spark discharge is generally used to produce nanoparticles, and in the present invention, the pin-to-plate structure rather than general rod-to-rod structure is used. The pin-to-plate structure according to the present invention is beneficial to produce nano-sized particles.

In the step 4) according to the present invention, the nanoparticles, which are charged with the same polarity with the ions generated by corona discharge, are induced to the micro/nano pattern of the substrate and can be focused and deposited on the exposed surface of the substrate, by introducing bipolar charged nanoparticles and ions generated by spark discharge into the reactor and then controlling the applied electric field.

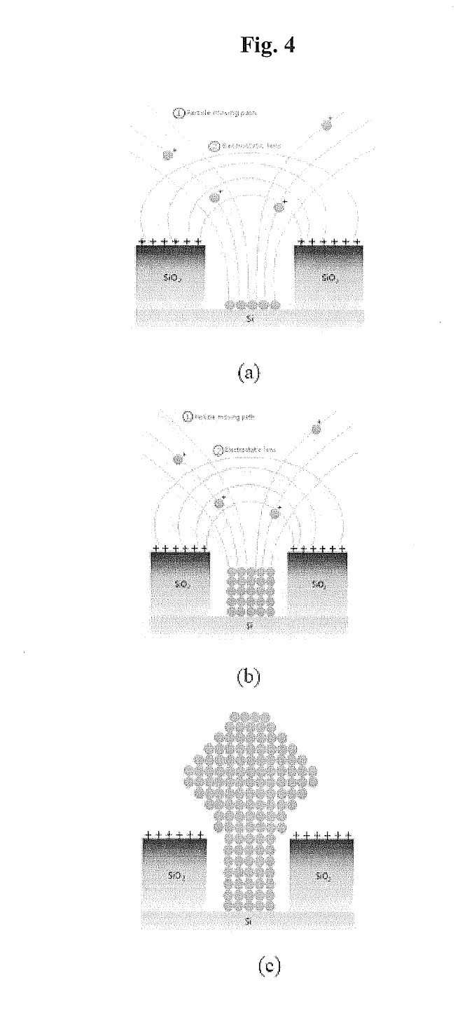

After the focused particles are somewhat accumulated, a rod-type structure is formed at first, and then it is converted to a petal shape when its height becomes higher than the thickness of the mask layer, by the principle described in FIG. 1 (see FIG. 4).

According to one preferred embodiment of the present invention, a carrier gas can be used for movement of the bipolar charged nanoparticles in the direction of the substrate in the reactor and for the focused patterning effect, and its representative examples may be nitrogen (N₂), helium (He), argon (Ar) and the like, but not limited thereto.

When the positive ions and positively-charged nanoparticles and the negative ions and negatively charged nanoparticles generated by spark discharge are inserted to the substrate, only the mono-polar charged nanoparticles and the ions having the same polarity are induced to near the substrate by the action of the electric field formed in the reactor, and the charged nanoparticles and the ions having the opposite polarity are removed through an outlet.

As illustrated above in FIG. 1, in general, because electrical mobility of gas ion is larger than electrical mobility of nanoparticle aerosol, and the ions inserted by corona discharge are enough, the ions arrive at the substrate in advance, and then accumulate an electric charge on the surface of the photoresist pattern layer. For example, when the positive ions accumulate an electric charge on the surface of the photoresist pattern layer in advance, a convex-type equipotential line is generated by the action of the accumulated positive ions and the electric field formed inside the reactor. And then, to the direction perpendicular thereto, the positively charged nanoparticles move to the center of the micro/nano pattern and then focused and deposited to form a nanoparticle structure. Further, when changing the direction of the electric field, the particles with the opposite polarity and the ions are induced, and therefore, the nanoparticles with the opposite polarity can be deposited on the micro/nano pattern.

Further, a nanoparticle structure having high aspect ratio may be formed by increasing the deposition of nanoparticles by controlling deposition time and gas flow rate.

Like this, the size of the nanoparticle structure formed according to the present invention varies depending on the size of the already formed micro/nano pattern from several nm to several μm, and its shape is also diverse. The various size and shape of the nanoparticle structure of the present invention may be more variously controlled depending on the deposition time and the pattern shape. For example, the nanoparticle structure of the present invention may have complicated 3-dimensional shape having 5 or more petals. Further, bipolar charged nanoparticles of two or more types are generated by sequentially spark discharging nanoparticles precursors of two or more types, and thereby a structure consisting of composite nanoparticles of two or more types as well as a single nanoparticle structure is effectively obtained.

Hereinafter, the present invention will be described in further detail with reference to examples, and the scope of the present invention cannot be limited thereby in any way.

### EXAMPLE 1

### Manufacture of Nanostructure

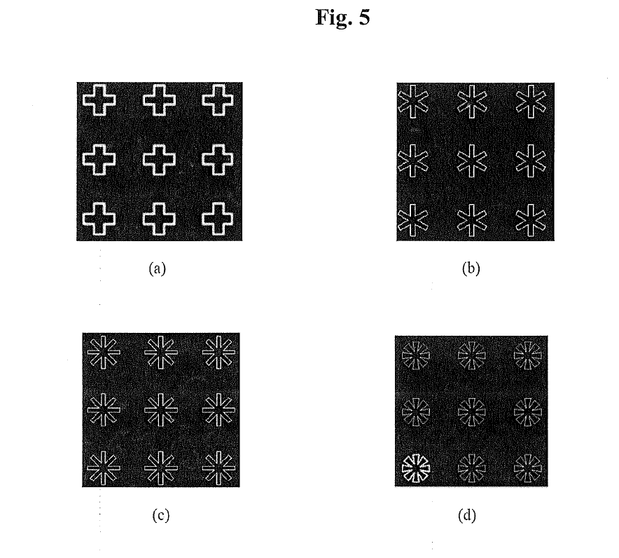

In this Example, experiments manufacturing flower-shaped structures having 4, 6 and 8 petals, were conducted representatively. As patterns for making 4, 6 and 8 petals, mask layers (SiO₂), which have perforated patterns formed by E-beam lithography as suggested in FIG. 5, were used. In FIG. 5, (a) is a cross-type pattern having length and breadth of 500 nm, respectively, (b) is a shape that 6 rectangles of 200 nm×500 nm are attached to a hexagon with side length of 200 nm, (c) is a shape that 8 rectangles of 200 nm×500 nm are attached to an octagon with side length of 200 nm, and (d) is a shape that 8 trapezoid having shorter sides of 200 nm and longer sides of 400 nm are attached to a 200 nm octagon.

Substrates having the patterns of FIG. 5 are equipped to the device illustrated in FIG. 2, respectively, and copper nanoparticles are focused and deposited under the following conditions. The size of the copper nanoparticles generated by spark discharge was 2 to 3 nm.

In the following Table, Applied Voltage for ion deposition condition for forming an electrostatic lens through ion deposition is for a corona discharge chamber, and Applied Voltage for nanoparticle focused deposition condition is for a spark discharge chamber.

TABLE 1

| | Ion Deposition | |
|---|---|---|
| | Condition for Forming | Nanoparticle Focused |
| Variables | Electrostatic Lens | Deposition Condition |
| Applied Voltage (kV) | 2.5 | 6 |
| Substrate Voltage (kV) | −1.5 | −2.5 |
| Carrier Gas | N₂ | N₂ |
| Carrier Gas Flow Rate | 4 | 4 |
| (lpm) | | |
| Deposition Time (min) | 20 | 90 |
| substrate | 0.1 micron-thick SiO₂ | 0.1 micron-thick SiO₂ |
| | pattern-formed silicon | pattern-formed silicon |

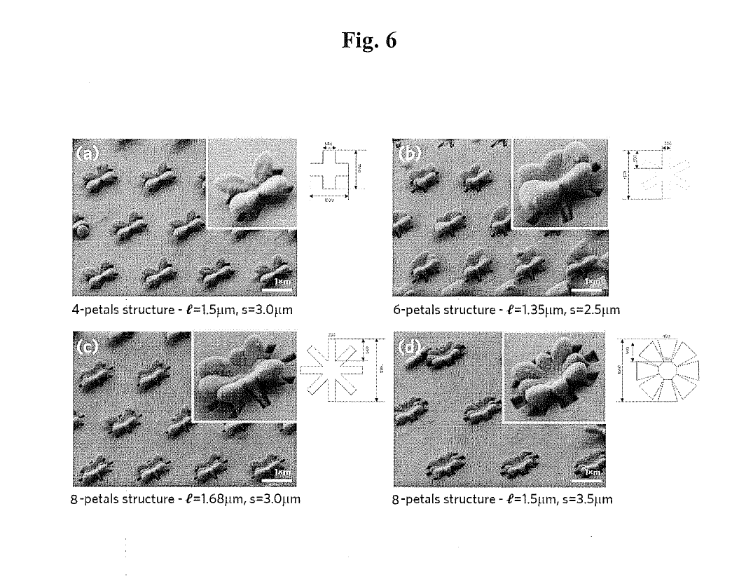

As a result, SEM images of flower-shaped nanoparticle structures formed as an array were shown in FIG. 6.

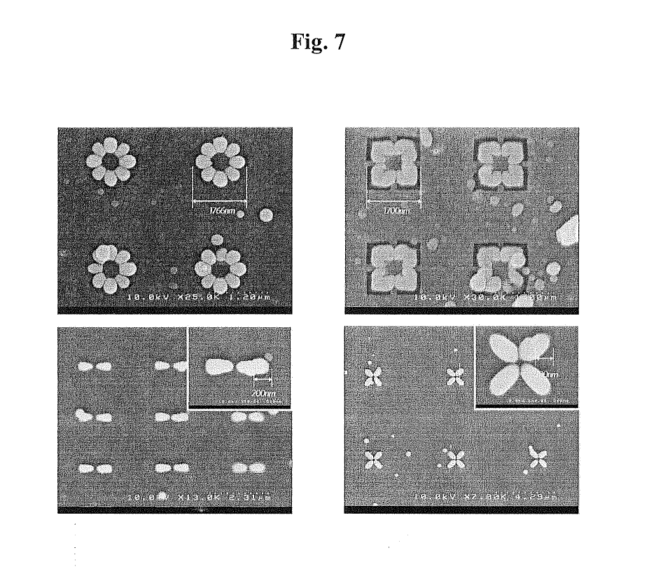

On the other hand, FIG. 7 is SEM images showing the results of copper nanoparticle focused deposition against various patterns illustrated in FIG. 3. As shown in FIG. 7, it can be found that the nanoparticles can be focused and deposited to various 3-dimensional structures by designing patterns variously.

### EXAMPLE 2

### SERS Test

A 3-dimensional composite structure array of copper nanoparticles and gold nanoparticles was manufactured, and application thereof as an optical device was tested through the surface enhanced Raman scattering (SERS) characteristic of the manufactured composite nanoparticle structure.

Gold nanoparticles are deposited to each of nanostructures of FIG. 6 by the same method with Example 1 to manufacture composite nanoparticle structure as an array type (Gold thickness: 50 nm).

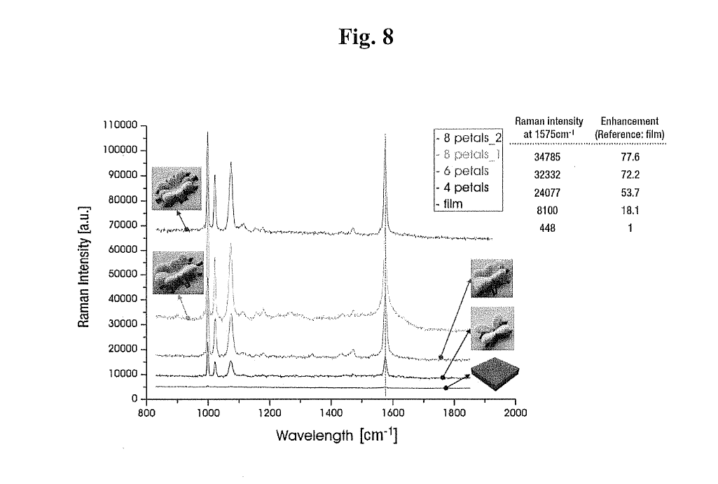

The composite nanoparticle structure manufactured as described above was dipped in a solution, wherein benzenethiol was dissolved in ethanol at the concentration of 1×10 M (molar ratio), for 3 hours so as to make the benzenethiol be adsorbed, and then the surface enhanced Raman scattering characteristic was measured by a general method. The result was shown in FIG. 8, and the test condition was as follows.

TABLE 2

| | |
|---|---|
| Incident Light Wavelength | 633 nm |
| Laser Power | 0.1 mW |
| Laser Diameter | 1 μm |
| Raman Shift Peak | 1575 cm⁻¹ |
| Exposure Time | 33 sec |

As shown in FIG. 8, it can be found that the Raman scattering signal is increased sharply as the number of petals increases. In particular, as compared with a film, there is an effect that the signal increases from 20 times to 70 times Further, it can be found that when the petals are 6 and 8, there is an effect of enhancing the signal two or more times, compared with the case of 4 petals. This shows that the 3-dimensional nanoparticle structure array according to the present invention is enough to be applied as a bio device and an optical device.

### INDUSTRIAL APPLICABILITY

The 3-dimensional structure, manufactured by the method according to the present invention, can manufacture 3-dimensional nanoparticle structures having various structures of more complicated and elaborate shape, for example, several nanometers to several micrometers as well as image of a flower having 5 or more petals, and this nanoparticle structure may be applied to optical and electric devices, for example, biosensors, solar cells and the like.

1-11. (canceled)

12. A method for manufacturing a nanoparticle structure, which comprises the steps of:
1) positioning a substrate, which has a micro or nano pattern formed by a mask layer having a perforated pattern, in a reactor, and then applying an electric field;
2) fabricating an electrostatic lens through a process comprising the steps of:
(i) generating ions by forming a non-uniform electric field through corona discharge; and then
(ii) accumulating the ions on the micro or nano pattern of the substrate positioned in the reactor; and
3) introducing into the reactor nanoparticles charged with the same polarity with the ions accumulated on the micro or nano pattern of the step 2), and then focused-depositing the nanoparticles into the perforated part of the micro or nano pattern of the substrate.

13. The method for manufacturing a nanoparticle structure according to claim 12, wherein the corona discharge of the step 2) is generated by applying a voltage ranging from 1 kV to 10 kV to a corona discharge chamber.

14. The method for manufacturing a nanoparticle structure according to claim 12, wherein the charged nanoparticles are generated together with ions by spark-discharging nanoparticle precursors in a spark discharge chamber, and the spark discharge is generated by applying a voltage ranging from 5 kV to 10 kV to the spark discharge chamber.

15. The method for manufacturing a nanoparticle structure according to claim 12, wherein the nanoparticle precursors are (i) conductive materials, (ii) conductive materials coated with non-conductive materials or (iii) semiconductive materials.

16. The method for manufacturing a nanoparticle structure according to claim 12, wherein the electric field of the step 1) is formed by applying a voltage ranging from −5 kV to 5 kV to the reactor.

17. The method for manufacturing a nanoparticle structure according to claim 12, wherein the ions generated in the step 2) and the charged nanoparticles introduced into the reactor in the step 3) are introduced into the reactor of the step 3) by using a carrier gas selected from nitrogen, helium and argon.

18. A nanoparticle structure having 3-dimensional shape, which is manufactured according to the method of claim 12.

19. The nanoparticle structure according to claim 18, which has image of a flower having five (5) or more petals.

20. The nanoparticle structure according to claim 18, which is composed of one or more types of nanoparticles.

21. A biosensor device manufactured from the nanoparticle structure of claim 18.

22. A solar cell device manufactured from the nanoparticle structure of claim 18.
